(19) United States
(12) Patent Application Publication
(10) Pub. No.: US 2025/0031557 A1
(43) Pub. Date: Jan. 23, 2025

(54) DISPLAY DEVICE AND MANUFACTURING METHOD OF DISPLAY DEVICE

(71) Applicant: Samsung Display Co., LTD., Yongin-si (KR)

(72) Inventors: Sang Duk LEE, Yongin-si (KR); Hoi Kwan LEE, Yongin-si (KR)

(73) Assignee: Samsung Display Co., LTD., Yongin-si (KR)

(21) Appl. No.: 18/657,088

(22) Filed: May 7, 2024

(30) Foreign Application Priority Data
Jul. 21, 2023 (KR) 10-2023-0095294

(51) Int. Cl. H10K 59/80; H10K 59/12

(52) U.S. Cl. CPC H10K 59/8792; H10K 59/1201

(57) ABSTRACT

A display device according to an embodiment of the disclosure includes a panel; a camera that does not overlap the panel in a plan view; a polarization layer disposed on the panel; a transmission layer extending to at least a portion of the polarization layer; and a coating layer having a larger area than the panel and disposed over the polarization layer and the transmission layer, wherein the transmission layer overlaps the camera in a plan view.

### CROSS-REFERENCE TO RELATED APPLICATIONS

This application claims priority under 35 U.S.C. § 119 from Korean Patent Application No. 10-2023-0095294 filed on Jul. 21, 2023 in the Korean Intellectual Property Office, the entire contents of which are incorporated herein by reference.

### BACKGROUND

### 1. Technical Field

The disclosure relates to a display device and a manufacturing method of the display device.

### 2. Description of the Related Art

As information technology is developed, an importance of a display device, which is a connection medium between users and information, has been highlighted. Therefore, a display device such as a liquid crystal display device (LCD), an organic light emitting display device (OLED), and the like has been increasingly used.

The display device may include a panel. The display device may include a window having a relatively larger area than the panel at an outermost portion of the display device to protect the panel and protect (or cover) lower members.

At this time, in order for the window to be tightly supported on the panel, a layer capable of supporting the window may be disposed. The layer capable of supporting the window needs to tightly support the window while not deteriorating light transmission characteristics of a camera included in the display device.

### SUMMARY

The disclosure is to provide a display device and a manufacturing method of the display device, in which a window is tightly supported so that structural stability and light transmission characteristics of a camera included in the display device can be improved.

A display device according to an embodiment of the disclosure may include a panel; a camera that does not overlap the panel in a plan view; a polarization layer disposed on the panel; a transmission layer extending to at least a portion of the polarization layer; and a coating layer having a larger area than the panel and disposed over the polarization layer and the transmission layer, wherein the transmission layer may overlap the camera in a plan view.

According to the embodiment, the transmission layer may have a light transmittance of about 90% or more.

According to the embodiment, the transmission layer may include at least one of an acryl-based material, a silicon-based material, a urethane-based material, an epoxy-based material, and a siloxane-based material.

According to the embodiment, the display device may further include a notch portion including an area where at least a portion of the panel may be removed, wherein the notch portion may overlap the camera and the transmission layer in a plan view.

According to the embodiment, an end of the transmission layer and an end of the coating layer may correspond to each other.

According to the embodiment, the transmission layer may integrally cover a side portion of the panel and a side portion of the polarization layer, and an end of the transmission layer may have different thicknesses from another end of the transmission layer.

According to an embodiment, the display device may include a display area and a non-display area, the polarization layer may include an opening overlapping the display area in a plan view, and the transmission layer may be disposed in the opening of the polarization layer.

According to the embodiment, the transmission layer may extend to the panel and may contact a side surface of the panel.

According to the embodiment, the display device may further include a black matrix that has at least a portion disposed on the polarization layer and has another portion disposed on the transmission layer, wherein the black matrix may not overlap the camera in a plan view.

According to an embodiment, the display device may further include a black matrix that has at least a portion disposed on the polarization layer and has another portion disposed on the transmission layer, wherein at least a portion of the black matrix may contact the transmission layer.

A manufacturing method of a display device according to an embodiment of the disclosure may include attaching a polarization layer protective film on a surface of a polarization layer; forming a transmission layer on the polarization layer protective film; detaching the polarization layer protective film from the polarization layer; attaching the polarization layer and the transmission layer to a panel; and forming a coating layer, wherein the coating layer may be formed over the polarization layer and the transmission layer, and at least a portion of the coating layer may be disposed (e.g., directly disposed) on the polarization layer.

According to an embodiment, the polarization layer protective film may include an organic material.

According to an embodiment, in the attaching of the polarization layer protective film to a surface of the polarization layer, the polarization layer protective film may be disposed to protrude more than the polarization layer.

According to an embodiment, in the forming the transmission layer on the polarization layer protective film, a base transmission layer may be applied (e.g., directly applied) on the polarization layer protective film, the base transmission layer may extend to the polarization layer, the base transmission layer and the polarizing layer protective film may be cut along a cutting line, and the base transmission layer may be cut to form the transmission layer.

According to the embodiment, the polarization layer may include an opening, in the attaching the polarization layer protective film to a surface of the polarization layer, the polarization layer protective film may be disposed on a surface of the polarization layer so that an edge of the polarization layer protective film and an edge of the polarization layer may coincide with each other, and in the forming the transmission layer on the polarization layer protective film, the transmission layer may be formed in the opening of the polarization layer.

A manufacturing method of a display device according to an embodiment of the disclosure may include forming a panel module by disposing a polarization layer on a panel; seating the panel module on a jig; forming a transmission layer; and forming a coating layer, wherein the transmission layer may be formed in an opening formed by the panel module and the jig, and may extend to at least a portion of the polarization layer and to the panel, the coating layer may be formed over the polarization layer and the transmission layer, and at least a portion of the coating layer may be disposed (e.g., directly disposed) on the polarization layer.

According to the embodiment, a panel protective film may be further disposed on a surface of the panel module before the panel module is seated on the jig, the panel protective film may include an organic material, and a release agent may be applied on the jig.

According to the embodiment, the jig may include a base on which the panel module may be disposed; and a protrusion protruding from the base in a thickness direction of the panel, and the protrusion may have a step shape.

According to the embodiment, the panel module may be disposed on the base of the jig and spaced apart from the protrusion of the jig, and the polarization layer may not overlap the protrusion of the jig in a plan view.

According to an embodiment, the panel module may be disposed on the base of the jig and spaced apart from the protrusion of the jig, and at least a portion of the polarization layer may overlap the protrusion of the jig in a plan view.

According to an embodiment of the disclosure, a display device and a manufacturing method of the display device may be provided in which structural stability can be ensured by supporting tightly a window, and light transmission characteristics of a camera included in the display device can be improved.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating a display device according to an embodiment;

FIGS. 2 and 3 are schematic plan views illustrating an embodiment of a display device;

FIG. 4 is a schematic cross-sectional view taken along line A-A′ of FIG. 1;

FIG. 5 is a schematic cross-sectional view of a display device taken along line B-B′ of FIG. 1;

FIG. 6 is a schematic cross-sectional view of a first embodiment taken along line C-C′ in FIG. 2;

FIG. 7 is a schematic cross-sectional view of a second embodiment taken along line C-C′ in FIG. 2;

FIG. 8 is a schematic cross-sectional view of a third embodiment taken along line D-D′ in FIG. 3;

FIG. 9 is a schematic plan view illustrating a polarization layer and a transmission layer of FIG. 8;

FIG. 10 is a schematic cross-sectional view of a fourth embodiment taken along line D-D′ in FIG. 3;

FIG. 11 is a flowchart illustrating a manufacturing method of the display device according to the first and third embodiments;

FIG. 12 is a schematic plan view illustrating an arrangement relationship of a polarization layer and a transmission layer according to the first embodiment;

FIGS. 13 to 15 are schematic cross-sectional views of step-by-step manufacturing processes of a polarization layer and a transmission layer according to the first embodiment;

FIGS. 16 and 17 are schematic cross-sectional views of step-by-step manufacturing processes of a polarization layer and a transmission layer according to the third embodiment;

FIG. 18 is a flowchart illustrating a manufacturing method of a display device according to the second and fourth embodiments;

FIGS. 19 and 20 are schematic cross-sectional views of step-by-step manufacturing processes of the display device according to the second embodiment; and

FIGS. 21 and 22 are schematic cross-sectional views of step-by-step manufacturing processes of the display device according to the fourth embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

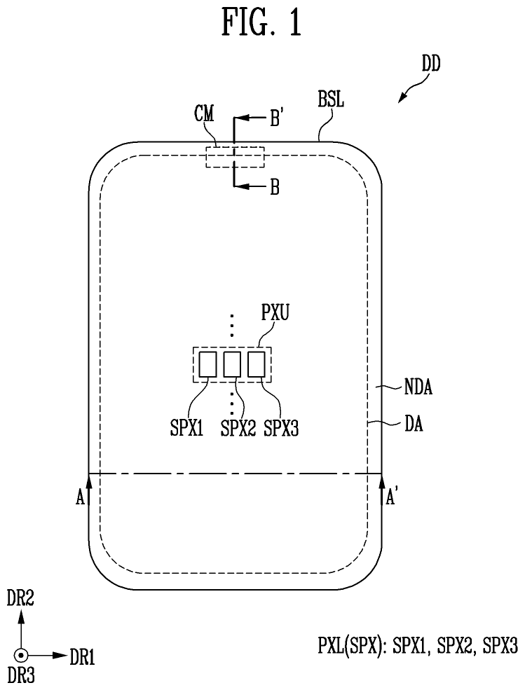

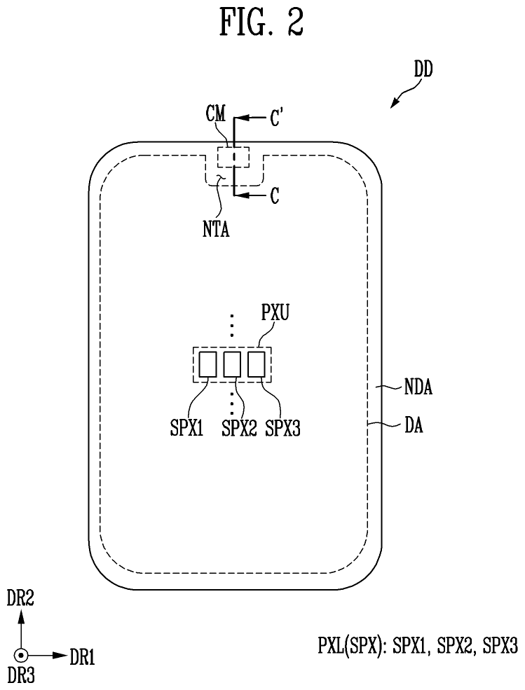

FIG. 1 is a schematic plan view illustrating a display device according to an embodiment. FIGS. 2 and 3 are schematic plan views illustrating an embodiment of a display device. FIGS. 2 and 3 schematically illustrate a display device DD and an arrangement of a camera CM according to an embodiment.

Referring to FIGS. 1 to 3, a structure of the display device DD and the arrangement of the camera CM will be described.

Referring to FIG. 1, the display device DD may be configured to emit light. The display device DD includes a light emitting element. According to the embodiment, the display device DD may be a device that displays moving images or still images. The display device DD can be used as a display screen of not only portable electronic devices such as a mobile phone, a smart phone, a tablet personal computer (tablet PC), a smart watch, a watch phone, a mobile communication terminal, an electronic notebook, an electronic book, a portable multimedia player (PMP), a navigation, an ultra-mobile PC (UMPCs), and the like, but also various products such as a television, a laptop, a monitor, a billboard, an internet of things (IOT), and the like. However, an application field of the display device DD may not be limited to a specific example.

The display device DD may be formed in a rectangular plane having a short side in the first direction DR1 and a long side in the second direction DR2 intersecting the first direction DR1. A corner where the short side of the first direction DR1 and the long side of the second direction DR2 meet may be formed to be round to have a curvature (i.e., a predetermined or selectable curvature) or may be formed to have a right angle. The planar shape of the display device DD may be not limited to a quadrangle and may be formed in a round shape such as a circle or an ellipse or in another polygonal shape. The display device DD may be formed to be approximately flat but may not be limited thereto. For example, the display device DD may include curved portions formed at left and right ends and having a constant curvature or a changing curvature. The display device DD may be flexibly formed to be curved, warped, bent, folded, or rolled.

In the disclosure, the first direction DR1 may be a row direction of the pixel PXL and may be a “horizontal” direction. The second direction DR2 may be a column direction of the pixel PXL. The third direction DR3 may be a display direction of the display device DD or a normal direction of a plane on which a base layer BSL may be disposed.

The display device DD may include a display area DA and a non-display area NDA. The non-display area NDA may mean an area other than the display area DA. The non-display area NDA may surround at least a portion of the display area DA. However, the disclosure may not be limited thereto.

The display area DA may mean an area in which the pixels PXL may be disposed. The non-display area NDA may mean an area in which the pixel PXL may not be disposed. A driving circuit portion, wires, and pads electrically connected to the pixel PXL of the display area DA may be disposed in the non-display area NDA.

According to an embodiment, the pixel PXL (or sub-pixels SPX) may include a first sub-pixel SPX1, a second sub-pixel SPX2, and a third sub-pixel SPX3. At least one of the first sub-pixel SPX1, the second sub-pixel SPX2, and the third sub-pixel SPX3 may form one pixel part PXU capable of emitting light of various colors. In FIG. 1, it is illustrated that each pixel PX includes three sub-pixels SPX1, SPX2, and SPX3, the first sub-pixel SPX1, the second sub-pixel SPX2, and the third sub-pixel SPX3, but embodiments of the disclosure may not be limited thereto.

According to the embodiment, the pixels PXL (or sub-pixels SPX) may be arranged according to a stripe or a PenTile® arrangement structure. However, the disclosure may not be necessarily limited thereto.

The first sub-pixel SPX1 may emit a first light, the second sub-pixel SPX2 may emit a second light, and the third sub-pixel SPX3 may emit a third light. Here, the first light may be light of a red wavelength band, the second light may be light of a green wavelength band, and the third light may be light of a blue wavelength band. The red wavelength band may be a wavelength band of about 600 nm to about 750 nm, the green wavelength band may be a wavelength band of about 480 nm to about 560 nm, and the blue wavelength band may be a wavelength band of about 370 nm to about 460 nm, however embodiments of the disclosure may not be limited thereto.

According to the embodiment, the display device DD may include a camera CM. The camera CM may obtain image information. For example, the camera CM may photograph objects and backgrounds.

The camera CM may be disposed in at least a portion of the display area DA or the non-display area NDA. For example, the camera CM may be disposed over the display area DA and the non-display area NDA. For example, the camera CM may overlap at least a portion of the display area DA and at least a portion of the non-display area NDA in a plan view. However, the disclosure may not be limited thereto.

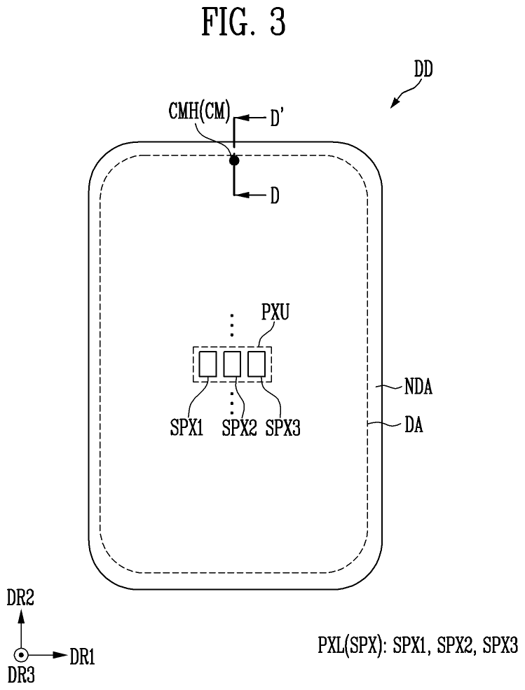

Referring to FIG. 2, according to an embodiment, the display device DD may further include a notch portion NTA. The notch portion NTA may be defined as an area in which at least a portion of the panel PNL (see FIG. 4) may be cut or removed.

The notch portion NTA may be formed (e.g., disposed) at an edge of one side of the display area DA. According to an embodiment, at least a portion of the display area DA may surround at least a portion of the notch portion NTA.

The notch portion NTA may provide an area where the camera CM can be disposed. The camera CM may be disposed in the notch portion NTA. The camera CM may be disposed to overlap the non-display area NDA in a plan view.

Referring to FIG. 3, the display device DD may further include a camera hole CMH. The camera hole CMH may be formed (e.g., disposed) in the display area DA. As the camera hole CMH may be disposed within the display area DA, the display device DD can minimize the non-display area NDA, thereby reducing a bezel of the display device DD and providing a large area of the display area DA.

The camera CM may be disposed in the camera hole CMH. For example, the camera CM may be disposed in an opening defined by the camera hole CMH. The camera CM may be disposed to overlap the display area DA in a plan view.

However, the disclosure may not be limited thereto. The display device DD may have various forms other than the embodiments shown in FIGS. 1 to 3, and the camera CM may have various arrangement forms within the display device DD.

With reference to FIG. 4, components included in the display device DD will be described.

FIG. 4 is a schematic cross-sectional view taken along line A-A′ of FIG. 1.

Referring to FIG. 4, the display device DD may include a panel PNL, a polarization layer POL, a black matrix BM, and a coating layer CTL.

The panel PNL may include a base layer BSL, a pixel circuit layer PCL, and a display layer DL.

The base layer BSL may form a base member on which components of the display device DD may be disposed. The base layer BSL may be a rigid or flexible substrate or film. For example, the base layer BSL may be a rigid substrate made of glass or tempered glass, a flexible substrate (or thin film) made of plastic or metal, or an insulating layer of at least one layer. According to the embodiment, the base layer BSL may include silicon (Si). The material and/or physical properties of the base layer BSL may not be particularly limited. According to the embodiment, the base layer BSL may be substantially transparent. Here, “substantially transparent” may mean that light can be transmitted at a level of one transmittance or more. In an embodiment, the base layer BSL may be translucent or opaque. Also, the base layer BSL may include a reflective material according to embodiments.

The pixel circuit layer PCL may be a layer including a pixel circuit for driving a light emitting element. The pixel circuit layer PCL may include conductive layers for forming pixel circuits and insulating layers disposed between the conductive layers. The pixel circuits may be electrically connected to the light emitting elements to provide electrical signals for the light emitting elements to emit light. For example, the pixel circuit layer PCL may include a thin film transistor.

The display layer DL may be disposed on the pixel circuit layer PCL. The display layer DL may be configured to emit light. According to the embodiment, the display layer DL may be provided in various forms. For example, the display layer DL may include an inorganic light emitting element including an inorganic material. However, the disclosure may not be limited to specific examples. According to the embodiment, the display layer DL may include an organic light emitting diode (OLED).

According to the embodiment, the display device DD may further include a lower cover (not shown) disposed under the panel PNL. In the disclosure, a “lower” direction may be defined as a direction opposite to a thickness direction (e.g., the third direction DR3) of the base layer BSL.

The lower cover may be disposed under the panel PNL. The lower cover may provide a surface on which the camera CM may be disposed. The camera CM may be disposed on the lower cover.

The polarization layer POL may be disposed on panel PNL. According to an embodiment, the polarization layer POL may contact one surface of the panel PNL.

The polarization layer POL may cover at least a portion of the display area DA of the display device DD. The polarization layer POL may have a shape corresponding to the panel PNL. For example, a planar shape of the polarization layer POL may be a quadrangle. However, the disclosure may not be limited thereto, and the planar shape of the polarization layer POL may be a shape such a round shape such as a circle or an ellipse, or may be a shape of another polygon.

The polarization layer POL may improve display quality of the display device DD by preventing reflection of external light applied to the display device DD. According to embodiments, the polarization layer POL may include a ¼λ wave retarder and/or a linear polarizer. According to embodiments, the ¼λ wave retarder may include cyclo-olefin polymer (COP), and the linear polarizer may include polyvinyl alcohol (PVA). However, the material for forming the polarization layer POL may not be particularly limited.

The polarization layer POL may support the coating layer CTL. The polarization layer POL may contact at least a portion of the coating layer CTL.

The polarization layer POL may protrude more outward than the panel PNL (e.g., in a direction in which a plane on which the base layer BSL may be disposed extends, or in the second direction DR2). An area of a surface (e.g., upper surface or lower surface) of the polarization layer POL may be larger than an area of a surface (e.g., upper surface or lower surface) of the panel PNL. At least a portion of the polarization layer POL may not overlap the panel PNL in a plan view.

Since the area of a surface of the polarization layer POL may be larger than the area of a surface of the panel PNL, the polarization layer POL may completely cover a surface of the panel PNL. Further, since the polarization layer POL protrudes more outward than the panel PNL, in case that the coating layer CTL having a larger area than the panel PNL is disposed on the polarization layer POL, the coating layer CTL can be more firmly supported.

The black matrix BM may be disposed on the polarization layer POL. At least a portion of the black matrix BM may be disposed (e.g., directly disposed) on the polarization layer POL. At least a portion of the black matrix BM may expose at least a portion of the polarization layer POL. At least a portion of the polarization layer POL may not overlap at least a portion of the black matrix BM.

The black matrix BM may block (e.g., absorb) at least a portion of external light applied to the display device DD. The black matrix BM may have a substantially opaque color. For example, the black matrix BM may further include a light blocking material to absorb light. For example, the light blocking material may include carbon black, titanium oxynitride, titanium black, phenylene black, aniline black, cyanine black, nigrosine acid black, black resin, or a combination thereof.

The coating layer CTL may be disposed on the polarization layer POL and the black matrix BM. At least a portion of the coating layer CTL may be disposed (e.g., directly disposed) on the polarization layer POL. At least a portion of the coating layer CTL may be disposed (e.g., directly disposed) on the black matrix BM. The coating layer CTL may protect a front surface of the display device DD. According to embodiments, the coating layer CTL may be a window. According to embodiments, the coating layer CTL may be a hard coating layer.

According to the display device DD of the disclosure, at least a portion of the coating layer CTL may be disposed (e.g., directly disposed) on the polarization layer POL so that an optically clear adhesive (OCA) may not be further disposed between the polarization layer POL and the coating layer CTL. Accordingly, a laminating process of applying the optically clear adhesive (OCA) on the polarization layer POL and attaching a window may be omitted. Thus, the process can be simplified, and a unit cost of the process can be reduced. Also, since at least a portion of the coating layer CTL may be disposed (e.g., directly disposed) on the polarization layer POL, the thickness of the display device DD may be reduced.

The coating layer CTL may protrude more outward than the panel PNL (e.g., in a direction in which a plane on which the base layer BSL may be disposed extends). An area of a surface (e.g., a lower surface) of the coating layer CTL may be larger than an area of a surface (e.g., an upper surface) of the panel PNL. At least a portion of the coating layer CTL may not overlap the panel PNL in a plan view. Since a surface of the coating layer CTL has a larger area than a surface of the panel PNL, the panel PNL may be protected.

According to embodiments, the coating layer CTL may include a transparent material. For example, the coating layer CTL may include at least one material selected from a group consisting of thermoplastic resins or thermosetting resins such as polymethylmethacrylate (PMMA), polyethylene terephthalate (PET), polycarbonate (PC), polystyrene (PS), polythylene naphthalate (PEN), polyethersulphone (PES), allyl resin, or the like. However, the disclosure may not be limited thereto.

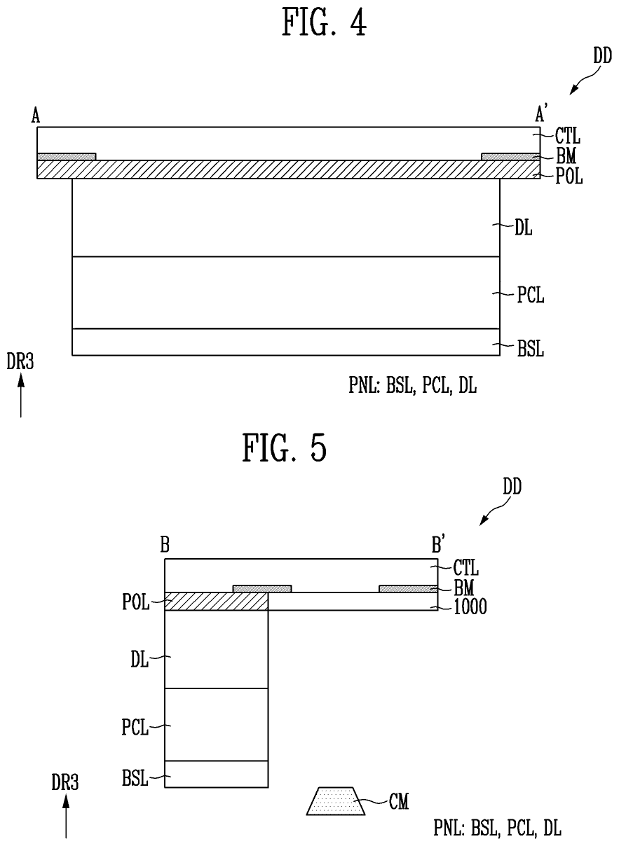

With reference to FIG. 5, an arrangement relationship between the camera CM and the components of the display device DD and configurations that can be further included in the display device DD will be described.

FIG. 5 is a schematic cross-sectional view of a display device taken along line B-B′ of FIG. 1.

Referring to FIG. 5, the camera CM may not overlap the panel PNL in a plan view. In a plan view, the camera CM may not overlap the black matrix BM. The camera CM may overlap an opening formed by the black matrix BM in a plan view.

The display device DD may further include a support structure layer 1000. The support structure layer 1000 may be disposed under the coating layer CTL. The support structure layer 1000 may contact at least a portion of the coating layer CTL. The support structure layer 1000 may support the coating layer CTL.

The support structure layer 1000 may overlap the camera CM in a plan view. The support structure layer 1000 may overlap at least a portion of the black matrix BM in a plan view. The support structure layer 1000 may not overlap the panel PNL in a plan view.

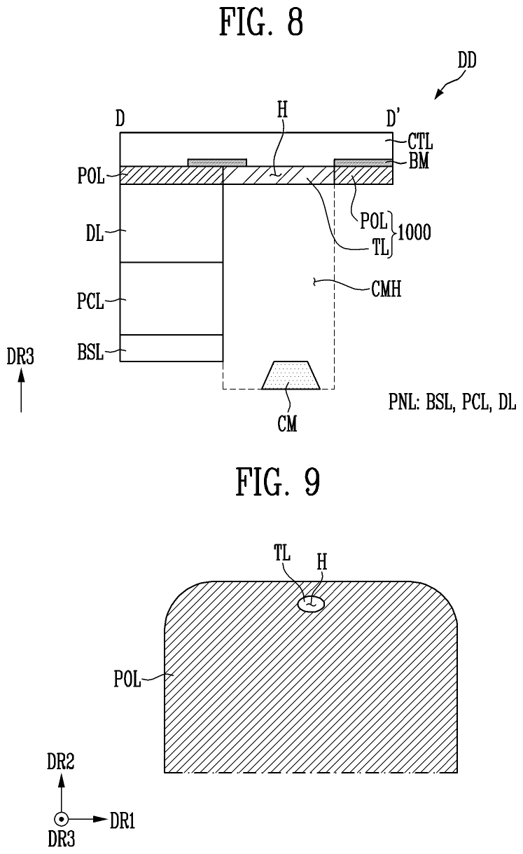

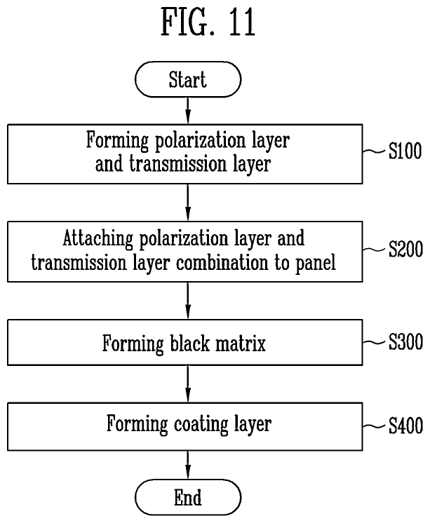

In this figure, a surface (e.g., upper surface) and another surface (e.g., lower surface) of the support structure layer 1000 may be shown as being disposed on a same plane as a surface (e.g., upper surface) and another surface (e.g., lower surface) of the polarization layer POL respectively, but the disclosure may not be limited thereto. This will be described later with reference to FIGS. 7 and 9.

At least a portion of the support structure layer 1000 may transmit light emitted from the camera CM. According to embodiments, the support structure layer 1000 may have light transmittance of about 90% or more in at least a partial area. Accordingly, light transmission characteristics of the support structure layer 1000 may be secured.

The display device DD may be manufactured by coating a window on the panel PNL to simplify an attachment process of the window and to make the display device DD thin. In case that the window is coated on the display panel to have a larger area than the panel PNL, a layer (e.g., the polarization layer) for supporting the window may be disposed. The layer for supporting the window may be required to secure light transmission characteristics of the camera included in the display device, but a comparative layer for supporting the window had a risk of lowering the light transmittance of the camera. For example, the comparative layer for supporting window does not have light transmission characteristics, and since the layer having no light transmission characteristics may be disposed in an area overlapping the camera CM, the light transmission characteristics of the camera CM included in the display device DD were lowered.

Since the display device DD according to an embodiment of the disclosure includes the support structure layer 1000, a coating layer CTL having a larger area than the panel PNL can be disposed on the panel PNL, and the layer having light transmission characteristics may be disposed in an area overlapping the camera CM to improve light transmission characteristics of the camera CM.

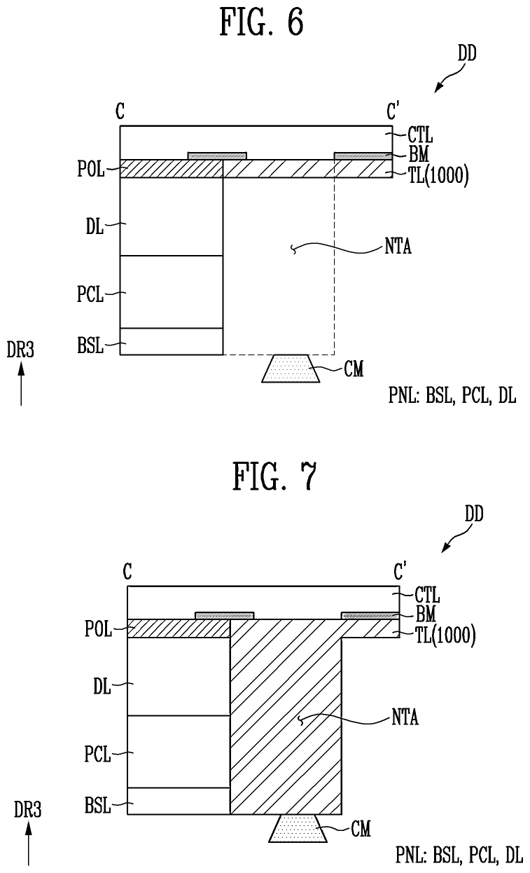

Hereinafter, structural characteristics of the support structure layer 1000 will be described with reference to FIGS. 6 to 10.

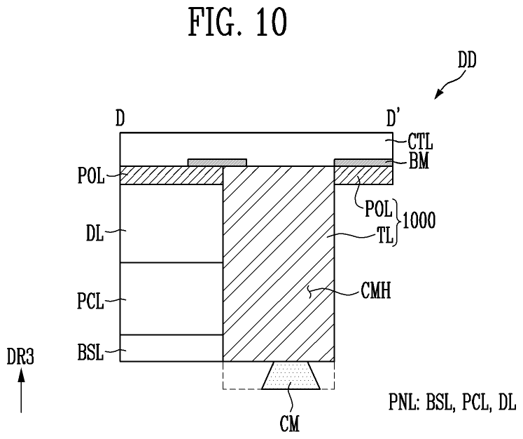

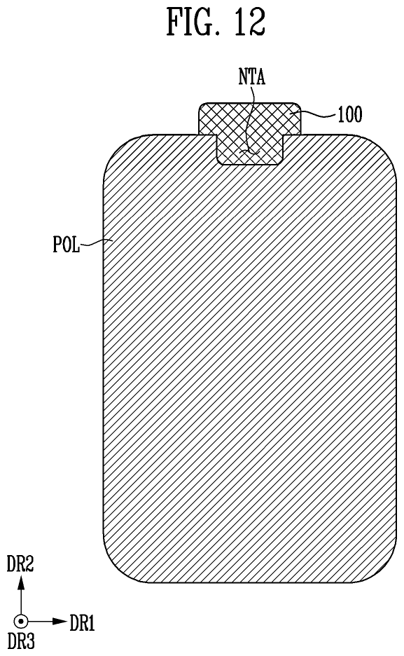

FIG. 6 is a schematic cross-sectional view of a first embodiment taken along line C-C′ in FIG. 2. FIG. 7 is a schematic cross-sectional view of a second embodiment taken along line C-C′ in FIG. 2. FIG. 8 is a schematic cross-sectional view of a third embodiment taken along line D-D′ in FIG. 3. FIG. 9 is a schematic plan view illustrating a polarization layer and a transmission layer of FIG. 8. FIG. 10 is a schematic cross-sectional view of a fourth embodiment taken along line D-D′ in FIG. 3.

Referring to FIG. 6, the support structure layer 1000 may include a transmission layer TL. According to embodiments, the support structure layer 1000 may be a transmission layer TL.

The coating layer CTL may be disposed over the polarization layer POL and the transmission layer TL. A portion of the coating layer CTL may be disposed on the polarization layer POL, and another portion of the coating layer CTL may be disposed on the transmission layer TL. The coating layer CTL may include a first portion disposed on the polarization layer POL and a second portion disposed on the transmission layer TL.

The transmission layer TL according to the first embodiment may be disposed in the notch portion NTA. The transmission layer TL may overlap the notch portion NTA in case of being viewed in a plan view. The transmission layer TL may be disposed under the coating layer CTL. The transmission layer TL may contact at least a portion of the coating layer CTL. An end of the transmission layer TL may correspond to an end of the coating layer CTL. For example, an end of the transmission layer TL may coincide with an end of the coating layer CTL in case of being viewed in a plan view. The transmission layer TL may overlap the camera CM in case of being viewed in a plan view.

According to the first embodiment, the transmission layer TL and the polarization layer POL may be disposed on a same layer. The transmission layer TL and the polarization layer POL may also be disposed on a same plane. A surface (e.g., upper surface) of the transmission layer TL and a surface (e.g., upper surface) of the polarization layer POL may be disposed on a same plane. The another surface (e.g., lower surface) of the transmission layer TL and another surface (e.g., lower surface) of the polarization layer POL may be disposed on a same plane. According to embodiments, the transmission layer TL and the polarization layer POL may have a same thickness. However, the disclosure may not be limited thereto. The transmission layer TL and the polarization layer POL may have different thicknesses.

According to embodiments, the transmission layer TL may extend to at least a portion of the polarization layer POL. The transmission layer TL may contact at least a portion of the polarization layer POL. For example, at least a portion of a side surface of the transmission layer TL and at least a portion of a side surface of the polarization layer POL may contact each other. The polarization layer POL may surround at least a portion of the transmission layer TL.

The transmission layer TL may contact at least a portion of the black matrix BM. A portion of the transmission layer TL may overlap the camera CM in a plan view.

The transmission layer TL may be an optically transparent layer. The transmission layer TL may include a material capable of transmitting light. For example, the transmission layer TL may have a light transmittance of about 90% or more. For example, the transmission layer TL may include one or more of an acryl-based material, a silicon-based material, a urethane-based material, an epoxy-based material, and a siloxane-based material.

In the display device DD in which the coating layer CTL has an area larger than that of the panel PNL, a configuration capable of supporting the coating layer CTL may be required between the coating layer CTL and the panel PNL to form the coating layer CTL to have a larger area than the panel PNL. For example, a configuration having a larger area than the panel PNL may be required to be disposed on the panel PNL so that the coating layer CTL can be applied on the panel PNL. In a comparative example, the polarization layer POL may extend to have a larger area than the panel PNL, so that the polarization layer POL can support the coating layer CTL in an area where the coating layer CTL protrudes more than the panel PNL. Accordingly, the polarization layer POL may be disposed in an area overlapping the camera CM, and there was a risk that light transmission characteristics of the camera CM may be reduced by the polarization layer POL.

According to an embodiment of the disclosure, the transmission layer TL may be disposed in an area overlapping the camera CM, and the transmission layer TL may be disposed under the coating layer CTL, so that the transmission layer TL may closely support the coating layer CTL. Accordingly, structural stability of the coating layer CTL may be secured. Light transmission characteristics of the camera CM may be improved.

Referring to FIG. 7, the second embodiment may be different from the first embodiment in that the transmission layer TL has a different shape. Hereinafter, contents that may overlap the above will be briefly described or omitted.

According to the second embodiment, the support structure layer 1000 may be a transmission layer TL.

The transmission layer TL according to the second embodiment may extend to the polarization layer POL and at least a portion of the panel PNL. For example, the transmission layer TL may contact the polarization layer POL and at least a portion of the panel PNL. The transmission layer TL may overlap the polarization layer POL and the panel PNL in case of being viewed from one direction (e.g., a direction in which a plane on which the panel PNL may be disposed extends). The transmission layer TL may have different thicknesses at an end and another end. A lower surface of the transmission layer TL may not be approximately flat. For example, the transmission layer TL may have a step.

According to the transmission layer TL according to the second embodiment, the transmission layer TL may integrally cover a side surface of the polarization layer POL and a side surface of the panel PNL, and the transmission layer TL may be arranged to have a relatively thick thickness. The transmission layer TL may more firmly support the coating layer CTL, and thus structural stability of the display device DD may be improved.

Referring to FIGS. 8 and 9, the third embodiment may be different from the previous embodiments in that the support structure layer 1000 includes at least a portion of the polarization layer POL.

According to the third embodiment, the support structure layer 1000 may include a portion of the polarization layer POL disposed outside and the transmission layer TL. The polarization layer POL according to the third embodiment may include an opening H. The opening H of the polarization layer POL may overlap the camera hole CMH in a plan view. The opening H of the polarization layer POL may overlap the display area DA in a plan view. The opening H of the polarization layer POL may have a circular shape. However, the disclosure may not be limited thereto. The opening H may have a polygonal shape.

The transmission layer TL according to the third embodiment may be disposed in the opening H of the polarization layer POL. The transmission layer TL may be disposed in the opening H of the polarization layer POL. The transmission layer TL may fill the opening H of the polarization layer POL. The transmission layer TL and the polarization layer POL may be disposed on a same layer. The transmission layer TL and the polarization layer POL may be disposed on a same plane. For example, a surface (e.g., upper surface) of the transmission layer TL and a surface (e.g., upper surface) of the polarization layer POL may be disposed on a same plane. Another surface (e.g., lower surface) of the transmission layer TL and another surface (e.g., lower surface) of the polarization layer POL may be disposed on a same plane. According to embodiments, the transmission layer TL and the polarization layer POL may have a same thickness. However, the disclosure may not be limited thereto. According to embodiments, the transmission layer TL may have a thickness different from that of the polarization layer POL.

The transmission layer TL and the polarization layer POL may extend to each other. For example, the polarization layer POL may cover the transmission layer TL. The transmission layer TL may entirely cover the opening H of the polarization layer POL. The transmission layer TL may share the same surface as the polarization layer POL. However, the disclosure may not be limited thereto.

Also, in the display device DD according to the third embodiment, since the transmission layer TL may be disposed in an area overlapping the camera CM, and the transmission layer TL may be disposed under the coating layer CTL, the coating layer CTL may be supported, thereby improving the light transmission characteristics of the camera CM.

Referring to FIG. 10, the fourth embodiment may be different from the third embodiment in that an area in which the transmissive layer TL may be disposed may be different.

According to the fourth embodiment, the support structure layer 1000 may include a portion of the polarization layer POL disposed outside and the transmission layer TL.

According to the fourth embodiment, the transmission layer TL may have a larger thickness than the polarization layer POL.

The transmission layer TL according to the fourth embodiment may extend to the polarization layer POL and at least a portion of panel PNL. For example, the transmission layer TL may contact the polarization layer POL and at least a portion of the panel PNL.

The transmission layer TL according to the fourth embodiment may integrally cover the side surface of the panel PNL and may be surrounded by the polarization layer POL. The transmission layer TL may integrally cover the side surface of the panel PNL, and the transmission layer TL may be disposed to have a relatively thick thickness. The transmission layer TL may more firmly support the coating layer CTL, and thus structural stability of the display device DD may be improved.

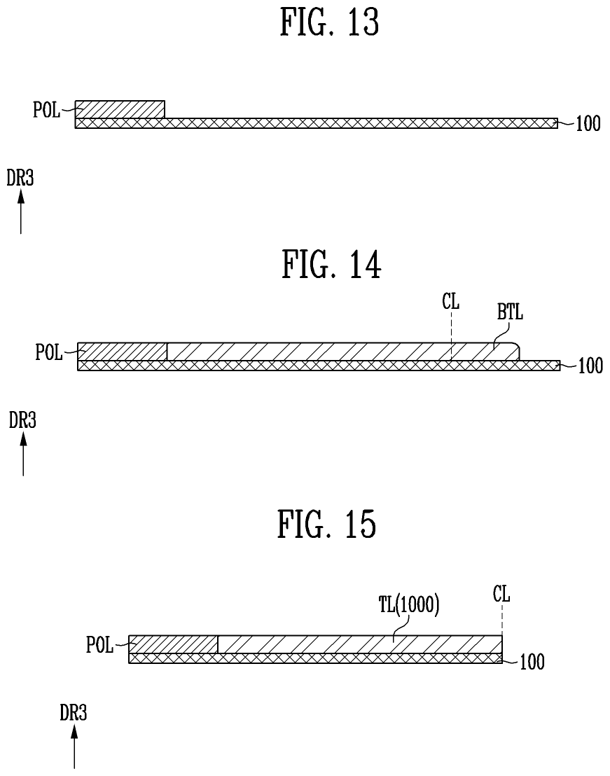

Hereinafter, a manufacturing method of the display device DD according to the first and third embodiments will be described with reference to FIGS. 11 to 17.

In the first and third embodiments, the transmission layer TL may be formed before the polarization layer POL is disposed on the panel PNL.

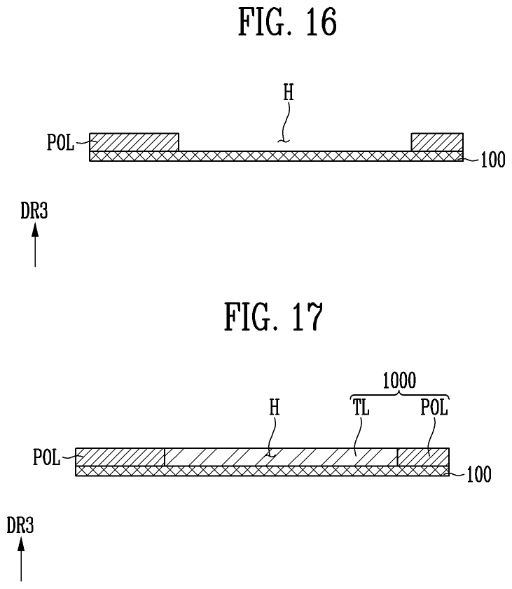

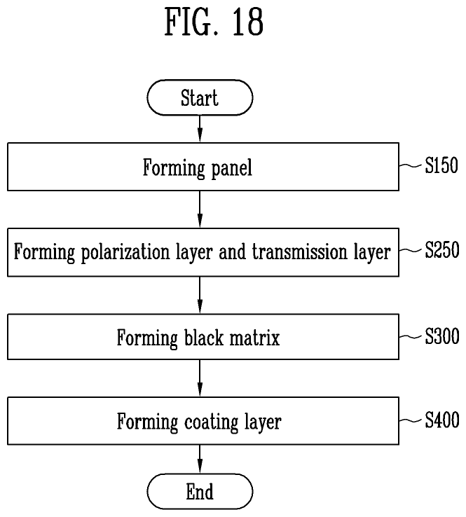

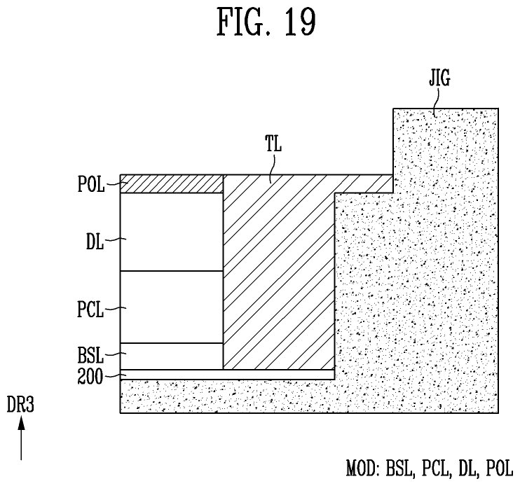

FIG. 11 is a flowchart illustrating a manufacturing method of the display device according to the first and third embodiments. FIG. 12 is a schematic plan view illustrating an arrangement relationship of a polarization layer and a transmission layer according to the first embodiment. FIGS. 13 to 15 are schematic cross-sectional views of step-by-step manufacturing processes of a polarization layer and a transmission layer according to the first embodiment. FIGS. 16 and 17 are schematic cross-sectional views of step-by-step manufacturing processes of a polarization layer and a transmission layer according to the third embodiment. FIGS. 13 to 17 are schematic cross-sectional views of step-by-step manufacturing process of forming the polarization layer and the transmission layer of FIG. 11 (S100).

First, the first embodiment will be described with reference to FIGS. 11 to 15, and then the third embodiment will be described with reference to FIGS. 11, 16, and 17.

Referring to FIG. 11, the manufacturing method of the display device DD according to the first and third embodiments includes forming a polarization layer and a transmission layer (S100), attaching the polarization layer and the transmission layer to a panel (S200), forming a black matrix (S300), and forming a window layer (S400).

Referring to FIGS. 12 and 13, the polarization layer POL may be prepared in forming the polarization layer and the transmission layer (S100). The polarization layer POL may have a shape corresponding to the display area DA of the display device DD and may have a larger area than the display area DA. For example, the polarization layer POL may have a structure in which a portion overlapping the notch portion NTA of the display device DD may be removed and may have a larger area than the display area DA.

The forming of the polarization layer and the transmission layer (S100) may include attaching the polarization layer protective film 100 on a surface of the polarization layer POL. The polarization layer protective film 100 may be disposed on a lower surface of the polarization layer POL. The lower surface of the polarization layer POL may be a surface contacting the panel PNL in case that the polarization layer POL is disposed on the panel PNL.

The polarization layer protective film 100 may be disposed to protrude more than the polarization layer POL. At least a portion of the polarization layer protective film 100 may not overlap the polarization layer POL in case of being viewed in a plan view. The polarization layer protective film 100 may extend beyond an end of the polarization layer POL. The polarization layer protective film 100 may extend beyond an edge of the display device DD.

The polarization layer protective film 100 may include an organic material. According to embodiments, the organic material may include at least one material selected from the group consisting of acryl resin, epoxy resin, phenol resin, polyamide resin, and polyimide resin. However, the disclosure may not be limited thereto. The polarization layer protective film 100 may include an inorganic material. According to embodiments, the inorganic material may include at least one material selected from the group consisting of silicon nitride (SiNₓ), aluminum nitride (AlNₓ), titanium nitride (TiNₓ), silicon oxide (SiOₓ), aluminum oxide (AlₓO_{y}), titanium oxide (TiOₓ), silicon oxycarbide (SiOₓC_{y}), and silicon oxynitride (SiOₓN_{y}).

Referring to FIG. 14, forming the polarization layer and the transmission layer (S100) may include forming the transmission layer TL on the polarization layer protective film 100. A base transmission layer BTL may be applied to the polarization layer protective film 100 to form the transmission layer TL. The base transmission layer BTL may be applied (e.g., directly applied) on the polarization layer protective film 100. The base transmission layer BTL may be applied to the polarization layer protective film 100 to protrude beyond the notch portion NTA of the display device DD.

The base transmission layer BTL may be disposed on the same plane as the polarization layer POL. The base transmission layer BTL may extend to the polarization layer POL. For example, the base transmission layer BTL may contact at least a portion of the polarization layer POL.

Referring to FIG. 15, the base transmission layer BTL applied to the polarization layer protective film 100 may be cut along a cutting line CL. The base transmission layer BTL and the polarization layer protective film 100 may be cut along the cutting line CL. The cutting line CL may be formed to correspond to an edge of the coating layer CTL of the display device DD. For example, referring to FIGS. 6 and 7, in case that the display device DD is manufactured after the base transmission layer BTL may be cut along the cutting line CL to form the transmission layer TL, an end of the transmission layer TL and an end of the coating layer CTL may correspond to each other. For example, an end of the transmission layer TL may coincide with an end of the coating layer CTL in case of being viewed in a plan view. The transmission layer TL and the coating layer CTL may form the same surface.

According to embodiments, a laser may be irradiated onto the base transmission layer BTL, and the base transmission layer BTL may be cut along the cutting line CL. However, the disclosure may not be limited thereto. According to embodiments, the base transmission layer BTL may be cut along the cutting line CL by an apparatus including a knife. In case that the base transmission layer BTL is cut, the transmission layer TL may be formed.

The forming of the polarization layer and the transmission layer (S100) may include detaching the polarization layer protective film 100 from the polarization layer POL. The polarization layer protective film 100 may be removed from the polarization layer POL. The polarization layer protective film 100 may be removed from the polarization layer POL to form the support structure layer 1000 according to the first embodiment.

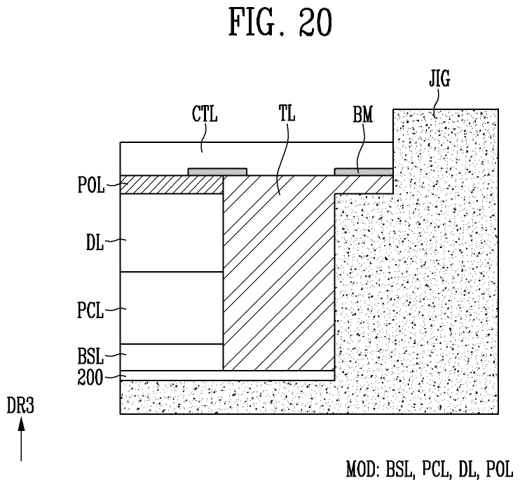

In the attaching the polarization layer and the transmission layer combination to the panel (S200), the polarization layer POL and the transmission layer TL from which the polarization layer protective film 100 may be removed may be disposed on the panel PNL. The manufacturing method of the display device DD may further include forming the panel PNL (S150) (see FIG. 18). The panel PNL may be formed in advance before the polarization layer POL and the transmission layer TL combination may be disposed.

The forming of the panel PNL (S150) may include patterning the pixel circuit layer PCL on the base layer BSL and patterning the display layer DL on the pixel circuit layer PCL.

In the forming of the pixel circuit layer PCL on the base layer BSL, the pixel circuit layer PCL including a pixel circuit including transistors and capacitors may be formed on the base layer BSL.

In this step, the base layer BSL may be prepared, and conductive layers and insulating layers for forming the pixel circuit layer PCL may be patterned on the base layer BSL. The conductive layers and insulating layers on the base layer BSL may be formed through a general patterning process (e.g., photolithography process) using a mask.

In the disclosure, the patterning process may include a deposition process and an etching process. For the deposition process, a physical vapor deposition (PVD) process (e.g., sputtering process), a chemical vapor deposition (CVD) process, an atomic layer deposition (ALD) process, and the like may be used. As the etching process, wet etching, dry etching, and the like may be used. However, the disclosure may not be limited to specific examples.

In the patterning of the display layer DL on the pixel circuit layer PCL, a light emitting element electrically connected to the pixel circuit may be formed on the pixel circuit layer PCL.

After the panel PNL is formed, the polarization layer POL and the transmission layer TL combination from which the polarization layer protective film 100 may be removed may be disposed on the panel PNL. The polarization layer POL and the transmission layer TL combination may be attached to the panel PNL. In this step, a laminating process may be performed to attach the polarization layer POL and the transmission layer TL combination to the panel PNL.

In the forming of the black matrix (S300), the black matrix BM may be formed on the polarization layer POL and the transmission layer TL combination. At least a portion of the black matrix BM may be deposited (e.g., directly deposited) on the polarization layer POL, and the remaining portion of the black matrix BM may be deposited (e.g., directly deposited) on the transmission layer TL. The black matrix BM may be etched to expose at least a portion of the polarization layer POL and at least a portion of the transmission layer TL. The black matrix BM may be etched to expose at least a portion of the transmission layer TL. For example, the black matrix BM may be etched to expose a portion of the transmission layer TL overlapping the area where the camera CM of the display device DD may be disposed.

In the forming of the coating layer CTL (S400), the coating layer CTL may be formed on the transmission layer TL and the polarization layer POL combination. The coating layer CTL may entirely cover the transmission layer TL and the polarization layer POL combination. The coating layer CTL may coat at least a portion of a surface (e.g., upper surface) of the transmission layer TL and of the polarization layer POL combination. A first portion of the coating layer CTL may cover the polarization layer POL, and a second portion of the coating layer CTL may cover the transmission layer TL.

Hereinafter, the third embodiment will be described with reference to FIGS. 11, 16 and 17. The third embodiment may be different from the first embodiment in that the cutting of the polarization layer protective film 100 after attaching the polarization layer protective film 100 can be omitted.

The polarization layer POL of the display device DD according to the third embodiment may have a shape corresponding to the display device DD, but may include an opening H. At least a portion of the polarization layer POL may be etched, so that the polarization layer may include the opening H having a circular shape or a polygonal shape.

According to the manufacturing method of the display device DD according to the third embodiment, in the attaching the polarization layer protective film 100, the polarization layer protective film 100 may be disposed to correspond to the polarization layer POL. For example, an end of the polarization layer protective film 100 and an end of the polarization layer POL may coincide with each other. For example, an edge of the polarization layer protective film 100 may be disposed to coincide with an edge of the polarization layer POL. As the edge of the polarization layer protective film 100 coincides with the edge of the polarization layer POL, cutting the polarization layer protective film 100 may not be further performed.

In the forming of the polarization layer and the transmission layer combination (S100), the transmission layer TL may be deposited (or applied) on the opening H of the polarization layer POL. The transmission layer TL may be disposed in the opening H of the polarization layer POL. The transmission layer TL may fill the opening H of the polarization layer POL. The transmission layer TL may be surrounded by the polarization layer POL. The transmission layer TL may be disposed on a same plane as the polarization layer POL. The transmission layer TL may extend to at least a portion of the polarization layer POL. For example, the transmission layer TL may contact at least a portion of the polarization layer POL.

Hereinafter, a manufacturing method of the display device DD according to the second and fourth embodiments will be described with reference to FIGS. 18 to 22.

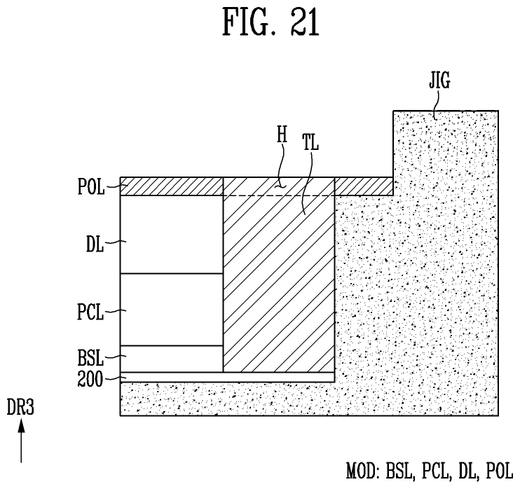

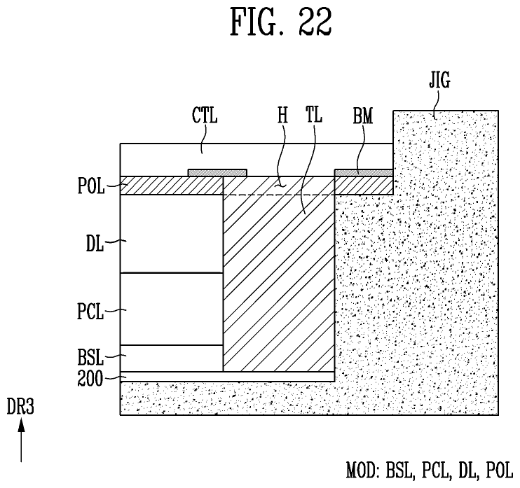

FIG. 18 is a flowchart illustrating a manufacturing method of a display device according to the second and fourth embodiments. FIGS. 19 and 20 are schematic cross-sectional views of step-by-step manufacturing processes of the display device according to the second embodiment. FIGS. 21 and 22 are schematic cross-sectional views of step-by-step manufacturing processes of the display device according to the fourth embodiment.

First, with reference to FIGS. 18 to 20, the second embodiment will be described.

According to the manufacturing method of the display device DD according to the second embodiment, the transmission layer TL may be formed after the polarization layer POL is disposed on the panel PNL.

Referring to FIG. 18, the manufacturing method of the display device DD according to the second and fourth embodiments may include forming the panel (S150), forming the polarization layer and the transmission layer combination (S250), and forming the black matrix (S300), and forming the coating layer (S400).

Referring to FIG. 19, forming the polarization layer and the transmission layer combination (S250) according to the second embodiment may include forming the polarization layer POL on the panel PNL, seating the panel module MOD on the jig, and forming the transmission layer TL.

In the forming of the polarization layer POL on the panel PNL, the polarization layer POL may be attached on the panel PNL. In this step, a laminating process may be performed to attach the panel PNL and the polarization layer POL.

The polarization layer POL may have a shape corresponding to the display area DA of the display device DD and may have a larger area than the display area DA. For example, the polarization layer POL may have a structure in which a portion overlapping the notch portion NTA of the display device DD may be etched, and may have a larger area than the display area DA.

After the polarization layer POL may be disposed on the panel PNL, the panel module MOD may be formed. The panel module MOD may include a panel PNL and a polarization layer POL.

The panel protective film 200 may be disposed on a surface (e.g., lower surface) of the panel module MOD. The panel protective film 200 may be attached to a surface (e.g., lower surface) of the panel PNL. The panel protective film 200 may be disposed under the panel module MOD before the panel module MOD is seated on the jig JIG, thereby protecting the lower surface of the panel module MOD. The panel protective film 200 may include an organic material. However, the disclosure may not be limited thereto. The panel protective film 200 may include an inorganic material.

In the seating the panel module MOD on the jig (JIG), the panel module MOD may be disposed on the jig JIG.

The jig JIG may have a structure including a base on which the panel module MOD may be capable of being disposed and a protrusion protruding from the base in the third direction DR3. The protrusion of the jig JIG may have a step shape.

A release agent may be applied on the jig JIG. The release agent may include at least one selected from the group consisting of a silicone-based release agent, a fluorine-based release agent, or both. However, the disclosure may not be limited thereto. Since the release agent may be applied on the jig JIG, the configuration of the display device DD can be not damaged and can be more readily separated in case that the display device DD is manufactured and then separated from the jig JIG.

The panel module MOD may be spaced apart from the protrusion of the jig JIG by a distance (e.g., a predetermined or selectable distance) and may be disposed on the base of the jig JIG. In case of being viewed in a plan view, the panel module MOD may not overlap the protrusion of the jig JIG. In case of being viewed in a plan view, the polarization layer POL may not overlap the protrusion of the jig JIG. In the forming of the transmission layer TL, the transmission layer TL may be formed in the opening formed by the panel module MOD and the jig JIG. The transmission layer TL may be disposed on the panel protective film 200 that does not overlap the panel module MOD in a plan view. The shape of the transmission layer TL may correspond to the shape of the jig JIG. For example, the shape of the transmission layer TL may be the same as the step shape of the jig JIG.

The transmission layer TL may extend to the polarization layer POL and at least a portion of the panel PNL. For example, the transmission layer TL may contact the polarization layer POL and at least a portion of the panel PNL.

Referring to FIG. 20, in the forming the black matrix (S300), the black matrix may be formed on the polarization layer POL and the transmission layer TL. In the forming of the coating layer (S400), the coating layer CTL may be formed on the polarization layer POL and the transmission layer TL.

After the coating layer CTL is formed, the display device DD including the panel protective film 200 may be separated from the jig. After the display device DD including the panel protective film 200 is separated from the jig JIG, the panel protective film 200 may be removed, and the display device DD may be completed.

A fourth embodiment will be described below with reference to FIGS. 21 and 22. The shape of the polarization layer POL and the transmission layer TL of the fourth embodiment may be different from that of the second embodiment.

According to the manufacturing method of the display device DD according to the fourth embodiment, the transmission layer TL may be formed after the polarization layer POL is disposed on the panel PNL.

In the forming of the polarization layer POL on the panel PNL, the polarization layer POL including the opening H may be disposed on the panel PNL. After the polarization layer POL is disposed on the panel PNL, the panel module MOD may be formed. The panel module MOD may be disposed on the jig JIG.

At least a portion of the polarization layer POL according to the fourth embodiment may overlap the protrusion of the jig JIG in a plan view.

In the forming the transmission layer TL, the transmission layer TL may be formed in the opening formed by the panel module MOD and the jig JIG. The transmission layer TL may be disposed in the opening H of the polarization layer POL. The transmission layer TL may fill the opening H of the polarization layer POL. The shape of the transmission layer TL may correspond to the shape of the opening H of the polarization layer POL. For example, in case that the opening H of the polarization layer POL has a circular shape, the transmission layer TL may have a circular shape.

The transmission layer TL may extend to the polarization layer POL and at least a portion of the panel PNL. For example, the transmission layer TL may contact the polarization layer POL and at least a portion of the panel PNL.

After the transmission layer TL is formed, in the forming of the black matrix (S300), the black matrix may be formed on the polarization layer POL and the transmission layer TL as in FIG. 22. In the forming the coating layer (S400), the coating layer CTL may be formed on the polarization layer POL and the transmission layer TL as in FIG. 22.

On the other hand, the timing at which the process performed in each step is performed may not be particularly limited and may be appropriately changed according to the process environment.

As described above, while the disclosure has been shown and described with reference to certain embodiments thereof, it will be understood by those skilled in the art that various changes in forms and details may be made therein without departing from the spirit and scope of the disclosure as defined by the appended claims and their equivalents.

Accordingly, the technical scope of the disclosure may be determined by the technical scope of the accompanying claims.

What is claimed is:

1. A display device comprising:
a panel;
a camera that does not overlap the panel in a plan view;
a polarization layer disposed on the panel;
a transmission layer extending to at least a portion of the polarization layer; and
a coating layer having a larger area than the panel and disposed over the polarization layer and the transmission layer,
wherein the transmission layer overlaps the camera in a plan view.

2. The display device of claim 1, wherein the transmission layer has a light transmittance of about 90% or more.

3. The display device of claim 2, wherein the transmission layer includes at least one of an acryl-based material, a silicon-based material, a urethane-based material, an epoxy-based material, and a siloxane-based material.

4. The display device of claim 1, further comprising:
a notch portion including an area where at least a portion of the panel is removed,
wherein the notch portion overlaps the camera and the transmission layer in a plan view.

5. The display device of claim 4, wherein an end of the transmission layer and an end of the coating layer correspond to each other.

6. The display device of claim 4, wherein
the transmission layer integrally covers a side surface of the panel and a side surface of the polarization layer, and
an end of the transmission layer has different thicknesses from another end of the transmission layer.

7. The display device of claim 1, wherein
the display device includes a display area and a non-display area,
the polarization layer includes an opening overlapping the display area in a plan view, and
the transmission layer is disposed in the opening of the polarization layer.

8. The display device of claim 7, wherein the transmission layer extends to the panel and contacts a side surface of the panel.

9. The display device of claim 4, further comprising:
a black matrix including at least a portion disposed on the polarization layer and another portion disposed on the transmission layer,
wherein the black matrix does not overlap the camera in a plan view.

10. The display device of claim 7, further comprising:
a black matrix including at least a portion disposed on the polarization layer and another portion disposed on the transmission layer,
wherein at least a portion of the black matrix contacts the transmission layer.

11. A manufacturing method of a display device comprising:
attaching a polarization layer protective film to a surface of a polarization layer;
forming a transmission layer on the polarization layer protective film;
detaching the polarization layer protective film from the polarization layer;
attaching the polarization layer and the transmission layer to a panel; and
forming a coating layer, wherein
the coating layer is formed over the polarization layer and the transmission layer, and
at least a portion of the coating layer is disposed directly on the polarization layer.

12. The manufacturing method of claim 11, wherein the polarization layer protective film includes an organic material.

13. The manufacturing method of claim 12, wherein in the attaching of the polarization layer protective film to the surface of the polarization layer, the polarization layer protective film is disposed to protrude more than the polarization layer.

14. The manufacturing method of claim 13, wherein in the forming of the transmission layer on the polarization layer protective film,
a base transmission layer is directly applied to the polarization layer protective film,
the base transmission layer extends to the polarization layer, and
the base transmission layer and the polarization layer protective film are cut along a cutting line to form the transmission layer.

15. The manufacturing method of claim 11, wherein
the polarization layer includes an opening,
in the attaching of the polarization layer protective film to a surface of the polarization layer, the polarization layer protective film is disposed on the surface of the polarization layer so that an edge of the polarization layer protective film and an edge of the polarization layer coincide with each other in a plan view, and
in the forming of the transmission layer on the polarization layer protective film, the transmission layer is formed in the opening of the polarization layer.

16. A manufacturing method of a display device comprising:
forming a panel module by disposing a polarization layer on a panel;
seating the panel module on a jig;
forming a transmission layer; and
forming a coating layer, wherein
the transmission layer is formed in an opening formed by the panel module and the jig, and is extended to the polarization layer and to at least a portion of the panel,
the coating layer is formed over the polarization layer and the transmission layer, and
at least a portion of the coating layer is disposed directly on the polarization layer.

17. The manufacturing method of claim 16, wherein
a panel protective film is further disposed on a surface of the panel module before the panel module is seated onto the jig,
the panel protective film includes an organic material, and
a release agent is applied on the jig.

18. The manufacturing method of claim 17, wherein
the jig includes a base on which the panel module is disposed, and a protrusion protruding from the base in a thickness direction of the panel, and
the protrusion has a step shape.

19. The manufacturing method of claim 18, wherein
the panel module is disposed on the base of the jig and is spaced apart from the protrusion of the jig, and
the polarization layer does not overlap the protrusion of the jig in a plan view.

20. The manufacturing method of claim 18, wherein
the panel module is disposed on the base of the jig and spaced apart from the protrusion of the jig, and
at least a portion of the polarization layer overlaps the protrusion of the jig in a plan view.
